(19) United States
(12) Patent Application Publication
(10) Pub. No.: US 2026/0092396 A1
(43) Pub. Date: Apr. 2, 2026

(54) CRYSTAL PREPARATION METHODS

(71) Applicant: MEISHAN BOYA ADVANCED MATERIALS CO., LTD., Meishan (CN)

(72) Inventors: Yu WANG, Meishan (CN); Peng GU, Meishan (CN)

(73) Assignee: MEISHAN BOYA ADVANCED MATERIALS CO., LTD., Meishan (CN)

(21) Appl. No.: 19/412,791

(22) Filed: Dec. 8, 2025

Related U.S. Application Data
(63) Continuation of application No. PCT/CN2023/100230, filed on Jun. 14, 2023.

(51) Int. Cl. C30B 23/02; C30B 7/00; C30B 29/36; C30B 29/40; C30B 33/06

(52) U.S. Cl. CPC C30B 23/025; C30B 7/005; C30B 29/36; C30B 29/403; C30B 33/06

(57) ABSTRACT

The present disclosure provides a crystal preparation method, including: obtaining a first wafer after a first treatment, using the first wafer after the first treatment as a first seed crystal to grow a precursor crystal based on a top-seeded solution growth method; performing a second treatment on the precursor crystal; and using the precursor crystal after the second treatment as a second seed crystal to grow a target crystal based on a physical vapor transport method.

### CROSS-REFERENCE TO RELATED APPLICATIONS

This application is a Continuation of International Application No. PCT/CN2023/100230, filed on Jun. 14, 2023, the contents of which are hereby incorporated by reference.

### TECHNICAL FIELD

The present disclosure generally relates to the field of crystal preparation technology, and more particularly, to a crystal preparation method.

### BACKGROUND

A silicon carbide single crystal has excellent physical and chemical properties and thus becomes an important material for manufacturing high-frequency and high-power devices. The physical vapor transport (PVT) method is a method for preparing a semiconductor crystal. However, due to the lack of high-quality seed crystals, inherent defects of a seed crystal may extend to an epitaxial layer during crystal growth using the PVT method, resulting in a high defect density of a prepared crystal.

The top-seeded solution growth (TSSG) method is used to prepare a high-quality silicon carbide crystal due to its low growth temperature and near thermodynamic equilibrium conditions. However, the thickness of a crystal prepared by the TSSG method is limited and cannot meet industrial production requirements.

Therefore, it is necessary to provide a crystal preparation method to prepare a large-sized and high-quality crystal.

### SUMMARY

One or more embodiments of the present disclosure provide a crystal preparation method. The method includes obtaining a first wafer after a first treatment; using the first wafer after the first treatment as a first seed crystal to grow a precursor crystal based on a top-seeded solution growth method; performing a second treatment on the precursor crystal; and using the precursor crystal after the second treatment as a second seed crystal to grow a target crystal based on a physical vapor transport method.

One or more embodiments of the present disclosure provide a seed crystal preparation method. The method includes performing a radial cutting on an off-axis seed crystal to obtain at least two seed crystal wafers; and obtaining a target seed crystal by splicing the at least two seed crystal wafers such that step directions of the spliced seed crystal wafers are opposite.

### BRIEF DESCRIPTION OF THE DRAWINGS

The present disclosure is further described by way of exemplary embodiments, which are described in detail through the drawings. These embodiments are not limiting. In these embodiments, the same reference numerals denote the same structures, wherein:

FIG. 1 is a flowchart illustrating an exemplary process for crystal preparation according to some embodiments of the present disclosure.

FIG. 2 is a flowchart illustrating an exemplary process for crystal preparation according to some embodiments of the present disclosure.

FIG. 3A is a flowchart illustrating an exemplary process for performing a first treatment on an off-axis wafer according to some embodiments of the present disclosure.

FIG. 3B is an exemplary top view of a cut first wafer II in FIG. 3A.

FIG. 3C is a schematic diagram illustrating step directions of a first seed crystal being opposite to a solution flow direction according to some embodiments of the present disclosure.

FIG. 4A is an exemplary cross-sectional view of a second wafer according to some embodiments of the present disclosure.

FIG. 4B is an exemplary cross-sectional view of a second wafer according to other embodiments of the present disclosure.

FIG. 4C is an exemplary cross-sectional view of a second wafer according to other embodiments of the present disclosure.

FIG. 5 is a schematic diagram illustrating an immersion angle according to some embodiments of the present disclosure.

In the drawings, 210 denotes a first wafer after a first treatment, 220 denotes a crystal growth layer, 230 denotes a crystal growth layer after a second treatment, 240 denotes a target crystal growth layer, 310 denotes an off-axis wafer, 320 denotes a cut first wafer, 321 and 321-1 denote a cut first wafer I, respectively, 322, 322-1, 322-2, and 322-3 denote a cut first wafer II, respectively, 330 denotes a first seed crystal, 400 denotes a second wafer, and 410 denotes a groove.

### DETAILED DESCRIPTION

To more clearly illustrate the technical solutions in the embodiments of the present disclosure, the drawings used in the description of the embodiments will be briefly introduced below. Obviously, the drawings in the following description are merely some examples or embodiments of the present disclosure. For those of ordinary skill in the art, without creative effort, the present disclosure can be applied to other similar scenarios based on these drawings. Unless obviously obtained from the context or the context illustrates otherwise, the same numeral in the drawings refers to the same structure or operation.

As shown in the present disclosure and the claims, unless the context clearly indicates an exception, the terms “a,” “an,” “one,” and/or “the” are not limited to the singular, and may also include the plural. Generally speaking, the terms “include” and “comprise” only indicate the inclusion of explicitly identified steps and elements, and these steps and elements do not constitute an exclusive list. The method or device may also include other steps or elements.

The present disclosure uses flowcharts to illustrate operations performed by a system according to embodiments of the present disclosure. It should be understood that the preceding or following operations are not necessarily performed precisely in sequence. Conversely, various steps may be processed in reverse order or simultaneously. Meanwhile, other operations may be added to these processes, or one or more operations discussed herein may be removed from these processes.

Some embodiments of the present disclosure provide a crystal preparation method. In the method, a first wafer after a first treatment is used as a first seed crystal, a high-quality precursor crystal may be grown based on a TSSG method, a precursor crystal after a second treatment is used as a second seed crystal, and a large-size and high-quality target crystal may be grown based on a PVT method.

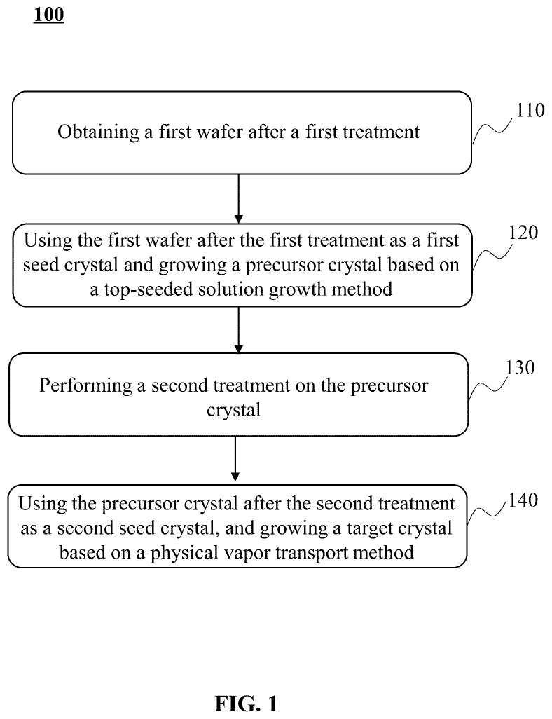

FIG. 1 is a flowchart illustrating an exemplary process for crystal preparation according to some embodiments of the present disclosure. In some embodiments, a process 100 may be performed by one or more components. In some embodiments, the process 100 may be automatically performed by a control system. Merely by way of example, the process 100 may be implemented through a control instruction. The control system controls, based on the control instruction, various components to complete various operations of the process 100. In some embodiments, the process 100 may be performed semi-automatically. Merely by way of example, one or more operations of the process 100 may be performed manually by an operator. In some embodiments, when completing the process 100, one or more additional operations not described may be added, and/or one or more operations discussed herein may be omitted. As shown in FIG. 1, the process 100 may include the following operations.

In 110, a first wafer after a first treatment is obtained.

In some embodiments, the first treatment may include, but is not limited to, grinding or polishing the first wafer. The grinding refers to processing a surface of the first wafer through a relative motion between a grinding tool and the first wafer under a preset pressure. In some embodiments, a surface of the grinding tool may be coated with or embedded with abrasive particles. The polishing refers to processing a surface of the first wafer using a polishing medium to reduce the roughness of the first wafer and make the surface of the first wafer flat. In some embodiments, the polishing medium may be polishing powders.

In some embodiments, before grinding or polishing the first wafer, the first treatment may further include cutting, etc. In some embodiments, the first wafer may be grown by a PVT method.

In some embodiments, the first wafer may include, but is not limited to, a silicon carbide wafer, an aluminum nitride wafer, etc.

It should be understood that a defect density of the first wafer prepared by the PVT method is relatively high. Therefore, it is needed for the first wafer to undergo the first treatment to make the surface of the first wafer after the first treatment flatter and reduce the defect density of the first wafer.

In some embodiments, a material of a seed crystal holder may include, but is not limited to, graphite, etc. When the first wafer after the first treatment is used as a first seed crystal to grow a precursor crystal based on the TSSG method, in order to prevent the solution from climbing to a backside of the first seed crystal through surface tension during crystal growth and reacting with the seed crystal holder, which leads to a decrease in quality of the prepared precursor crystal, a thickness of the first wafer after the first treatment needs to be greater than a first thickness threshold. However, if the thickness of the first seed crystal is too large, it may lead to the weight of the first seed crystal being too large, which may cause the first seed crystal to detach from the seed crystal holder due to a bonding strength issue during the preparation of the precursor crystal in the TSSG method. Therefore, the thickness of the first wafer after the first treatment needs to be less than a second thickness threshold. The first thickness threshold and the second thickness threshold may be empirical values, preset values, etc.

In some embodiments, the thickness of the first wafer after the first treatment may be in a range of 0.35 mm-10 mm. In some embodiments, the thickness of the first wafer after the first treatment may be in a range of 0.5 mm-9.5 mm. In some embodiments, the thickness of the first wafer after the first treatment may be in a range of 1 mm-9 mm. In some embodiments, the thickness of the first wafer after the first treatment may be in a range of 1.5 mm-8.5 mm. In some embodiments, the thickness of the first wafer after the first treatment may be in a range of 2 mm-8 mm. In some embodiments, the thickness of the first wafer after the first treatment may be in a range of 2.5 mm-7.5 mm. In some embodiments, the thickness of the first wafer after the first treatment may be in a range of 3 mm-7 mm. In some embodiments, the thickness of the first wafer after the first treatment may be in a range of 3.5 mm-6.5 mm. In some embodiments, the thickness of the first wafer after the first treatment may be in a range of 4 mm-6 mm. In some embodiments, the thickness of the first wafer after the first treatment may be in a range of 4.5 mm-5.5 mm.

In some embodiments of the present disclosure, by controlling the thickness of the first wafer after the first treatment, it is possible to not only ensure that the first wafer has a certain thickness for back dissolution when used as the first seed crystal for preparing the precursor crystal in the TSSG method, but also prevent the solution from climbing to the backside of the first seed crystal and reacting with the seed crystal holder, and ensure that the first seed crystal does not detach from the seed crystal holder due to excessive weight.

When the first wafer after the first treatment is used as the first seed crystal for preparing the precursor crystal in the TSSG method, the solution may exhibit a flow direction spreading from the center to the periphery under a centrifugal force. If the first wafer is an off-axis wafer, a portion of the step directions of the off-axis wafer may be the same as the solution flow direction, resulting in more defects in the crystal grown in that portion. In some embodiments, when the first wafer is the off-axis wafer, the first treatment may further include performing a radial cutting on the first wafer to obtain at least two cut first wafers (i.e., first wafers after cutting), and splicing the at least two cut first wafers such that step directions of the spliced cut first wafers are opposite, which can achieve that when the spliced cut first wafers are used as the first seed crystal for preparing the precursor crystal in the TSSG method, the flow direction of the solution is opposite to the step direction of the first seed crystal.

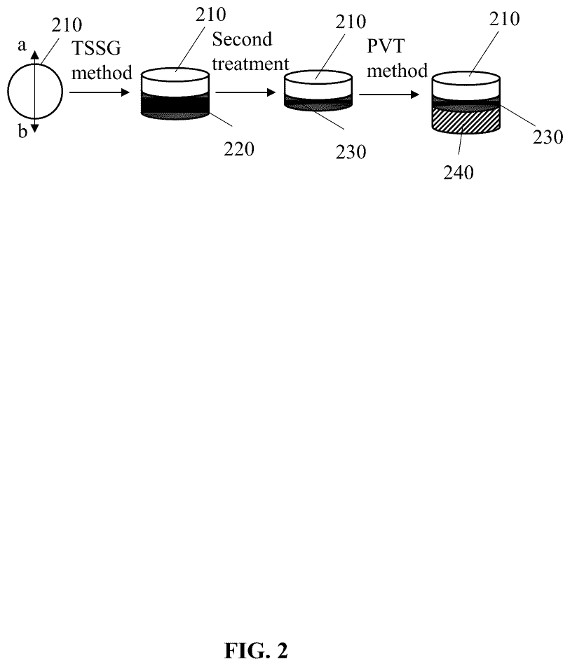

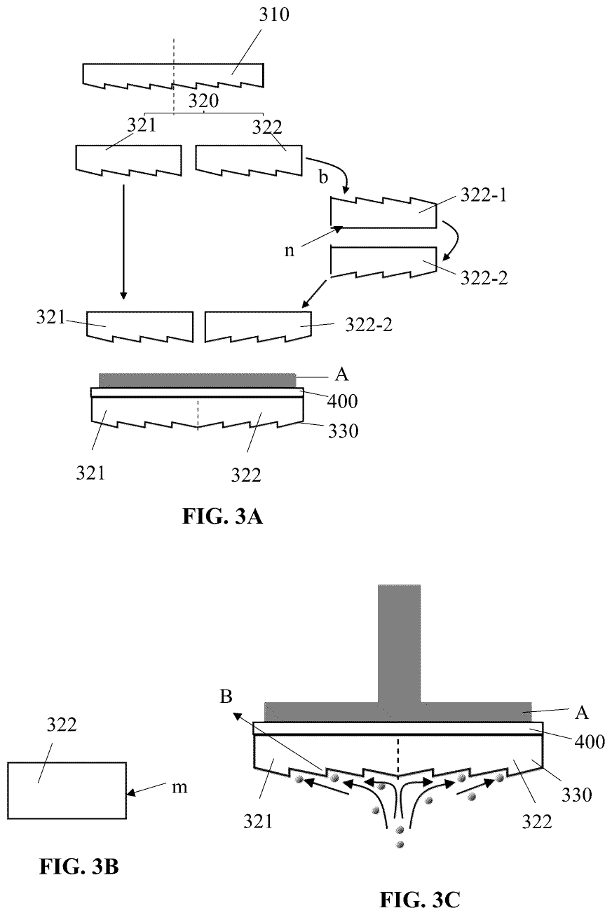

FIG. 2 is a flowchart illustrating an exemplary process for crystal preparation according to some embodiments of the present disclosure. FIG. 3A is a flowchart illustrating an exemplary process for performing a first treatment on an off-axis wafer according to some embodiments of the present disclosure. FIG. 3B is an exemplary top view of a cut first wafer II in FIG. 3A. FIG. 3C is a schematic diagram illustrating step directions of a first seed crystal being opposite to a solution flow direction according to some embodiments of the present disclosure.

In some embodiments, as shown in FIG. 3A, when the first wafer is an off-axis wafer 310, the radial cutting may be performed on the off-axis wafer 310 to obtain two cut first wafers 320. The radial cutting refers to cutting along a diameter direction or a direction perpendicular to an axis. As shown in FIG. 2, the radial cutting may be represented by a double arrow ab. The off-axis wafer refers to a wafer in which a crystallographic c-axis (the longest axis) is deflected by a preset angle toward a crystal orientation direction. In some embodiments, the off-axis wafer may be obtained by performing a mechanical processing (e.g., cutting or beveling) on a wafer. It should be understood that, due to limitations of the mechanical processing, the step directions of the off-axis wafer are always along a single direction. As shown in FIG. 3A, the step directions of the off-axis wafer 310 are consistent and all point to one side. Therefore, in order to achieve that the solution flow direction is opposite to all step directions of the first seed crystal, the at least two cut first wafers 320 need to be spliced.

The at least two cut first wafers 320 may be spliced in various ways such that the step directions of the spliced cut first wafers 320 are opposite. Merely by way of example, when splicing two cut first wafers 320, one (e.g., the cut first wafer I 321 as shown in FIG. 3A) of the two cut first wafers 320 may be kept stationary, and the other (e.g., the cut first wafer II 322 as shown in FIG. 3A) may undergo at least one mirror transformation. The cut first wafer II 322 after the mirror transformation may be spliced with the stationary cut first wafer I 321 such that the step directions of the spliced cut first wafers are opposite. The mirror transformation may include performing a 180° rotation about a certain axis (e.g., an edge line, a vertical central axis, or a horizontal central axis of the cut first wafer II).

In some embodiments, the first treatment may further include performing at least one of rotation processing or flipping processing on at least one of the at least two cut first wafers 320. The at least one of the rotation processing or the flipping processing may include performing a rotation by a preset angle about a certain axis (e.g., an edge line, a vertical central axis, or a horizontal central axis of the cut first wafer). Merely by way of example, as shown in FIG. 3A, when the first wafer is the off-axis wafer 310, the radial cutting may be performed on the off-axis wafer 310 to obtain the cut first wafer I 321 and the cut first wafer II 322. The cut first wafer I 321 may be kept stationary. The cut first wafer II 322 may be rotated clockwise by 180° (in the direction indicated by the arrow “b” in FIG. 3A) about its edge line (the edge line indicated by “m” in FIG. 3B) as a rotation axis to obtain the cut first wafer II 322-1 as shown in FIG. 3A. Then, the cut first wafer II 322-1 may be rotated by 180° about its edge line (the edge line indicated by “n” in FIG. 3A) as a rotation axis to obtain the cut first wafer II 322-2. The cut first wafer II 322-2 may then be spliced with the cut first wafer I 321. As shown in FIG. 3A, the spliced cut first wafers (which may also be referred to as the first seed crystal 330) may be obtained. As shown in FIG. 3A and FIG. 3C, in the spliced cut first wafers (which may also be referred to as the first seed crystal 330), step directions of the cut first wafer I 321 are opposite to step directions of the cut first wafer II 322. As shown in FIG. 3C, when the spliced cut first wafers are used as the first seed crystal 330 for preparing the precursor crystal in the TSSG method, the step directions of the first seed crystal 330 are opposite to the solution flow direction (which may be understood as the step “B” in FIG. 3C hindering solution flow or the solution flow colliding with the step “B” in FIG. 3C). The step “B” in FIG. 3C may be understood as a cut mark parallel to an axis of the first seed crystal 330.

Embodiments of the present disclosure do not limit the shape of the off-axis wafer 310. For example, the off-axis wafer 310 may be a cuboid, a cube, a cylinder, etc. For example, as shown in FIG. 3A-FIG. 3B, the off-axis wafer 310 may be a cuboid. In some embodiments, a cross-section of the off-axis wafer 310 may be a regular or irregular shape, such as a polygon (e.g., rectangle or square), circle, ellipse, etc. In some embodiments, the shape of the spliced cut first wafers may also be changed by cutting an edge of the spliced cut first wafers. For example, the first seed crystal 330 shown in FIG. 3A is a cuboid and may be cut to obtain a cylindrical seed crystal.

In some embodiments, when the first wafer (which may also be referred to herein as the off-axis wafer 310) is a cylinder, the radial cutting may be performed on two cylindrical first wafers with opposite step directions, respectively, to obtain two cut first wafers with opposite step directions. Then, the two cut first wafers with opposite step directions may be spliced to obtain spliced cut first wafers with opposite step directions, and the spliced cut first wafers form a cylinder.

In some embodiments of the present disclosure, by performing the radial cutting on the first wafer to obtain at least two cut first wafers, splicing the at least two cut first wafers such that step directions of the spliced cut first wafers are opposite, and using the spliced cut first wafers as the first seed crystal to grow the precursor crystal in the TSSG method, the step directions of the first seed crystal are opposite to the solution flow direction and step bunching behavior can be significantly suppressed, which is beneficial for reducing micro-defects and macro-defects, thereby improving the quality of the prepared precursor crystal and making the overall morphology of the crystal more flat and smooth.

It should be understood that, since the radial cutting and the splicing processing are performed on the first wafer, if the spliced cut first wafers are directly bonded to the seed crystal holder and used as the first seed crystal to prepare the precursor crystal in the TSSG method, during crystal growth, the solution may rise along a splicing gap of the spliced cut first wafers under capillary action to contact and react with the seed crystal holder, resulting in lower quality of the prepared precursor crystal. In some embodiments, to avoid the above situation, the at least two cut first wafers may be spliced by bonding them to a second wafer. Merely by way of example, as shown in FIG. 3A and FIG. 3C, the cut first wafer I 321 and the cut first wafer II 322 are spliced to obtain the spliced cut first wafers (which may also be referred to as the first seed crystal 330). The first seed crystal 330 may be bonded to one surface of a second wafer 400. Another surface of the second wafer 400 may be bonded to a seed crystal holder “A.”

As shown in FIG. 3A and FIG. 3C, the second wafer 400 may be located between the first seed crystal 330 and the seed crystal holder “A” and may be used for bonding the first seed crystal 330 and the seed crystal holder “A.” In some embodiments, the second wafer 400 may include an equiaxed crystal wafer, an off-axis wafer, etc. In some embodiments, a material of the second wafer 400 may be the same as or different from a material of the first seed crystal 330. In some embodiments, the shape of the second wafer 400 may be the same as or different from the shape of the first seed crystal 330.

The spliced cut first wafers may be bonded to the second wafer by thermal bonding. The spliced cut first wafers and the second wafer may also be bonded by other means. For example, the other means may include adhesive bonding, etc. A bonding means between the second wafer and the seed crystal holder may be the same as or different from a bonding means between the spliced cut first wafers (which may also be referred to as the first seed crystal) and the second wafer.

In some embodiments of the present disclosure, by bonding the spliced cut first wafers (which may also be referred to as the first seed crystal) to one surface of the second wafer, and bonding the other surface of the second wafer to the seed crystal holder, it is possible to avoid direct contact and reaction between the solution and the seed crystal holder through the splicing gap during the process of preparing the precursor crystal using the first seed crystal in the TSSG method, which is beneficial for improving the quality of the prepared precursor crystal.

In some embodiments, a groove may be provided at a preset height on the second wafer to further reduce an amount of solution climbing to the surface of the seed crystal holder. In some embodiments, the preset height may refer to a distance between a lowest end of the groove of the second wafer and a bottom surface of the second wafer. The preset height may be a preset value, a default value, etc. In some embodiments, the groove may include various structures (e.g., an annular structure). In some embodiments, a longitudinal cross-section of the groove may have any shape (e.g., a regular or irregular shape such as a polygon, a circle, etc.). In some embodiments, a depth of the groove may refer to a distance between a farthest point of the groove and a side surface of the second wafer. In some embodiments, an inclination of the groove may refer to an angle between an inclined side of the groove and a horizontal plane.

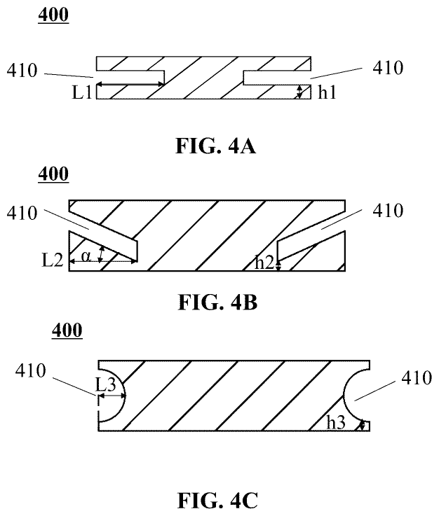

As shown in FIG. 4A, an annular groove 410 having a rectangular longitudinal cross-section is provided at a preset height (shown as “h1” in FIG. 4A) of the second wafer 400. A depth of the groove 410 (which may be understood as a length of the rectangle) may be represented as “L1” in FIG. 4A. As shown in FIG. 4B, an annular groove 410 having a parallelogram-shaped longitudinal cross-section is provided at a preset height (shown as “h2” in FIG. 4B) of the second wafer 400. A depth of the groove 410 may be represented as “L2” in FIG. 4B, and an inclination of the groove 410 is represented as “a.” As shown in FIG. 4C, an annular groove 410 having a semicircular longitudinal cross-section is provided at a preset height (shown as “h3” in FIG. 4C) of the second wafer 400. A depth of the groove 410 (which may also be understood as a radius of the semicircle) may be represented as “L3” in FIG. 4C.

When using the spliced cut first wafers as the first seed crystal to prepare the precursor crystal based on the TSSG method, in order to allow the solution to better wet the entire splicing gap under the action of surface tension, and make the crystal growth be performed at the splicing gap to close the entire splicing gap, in some embodiments, the first treatment may further include performing a third treatment on the spliced cut first wafers such that ends of the at least two cut first wafers close to the splicing gap form an immersion angle.

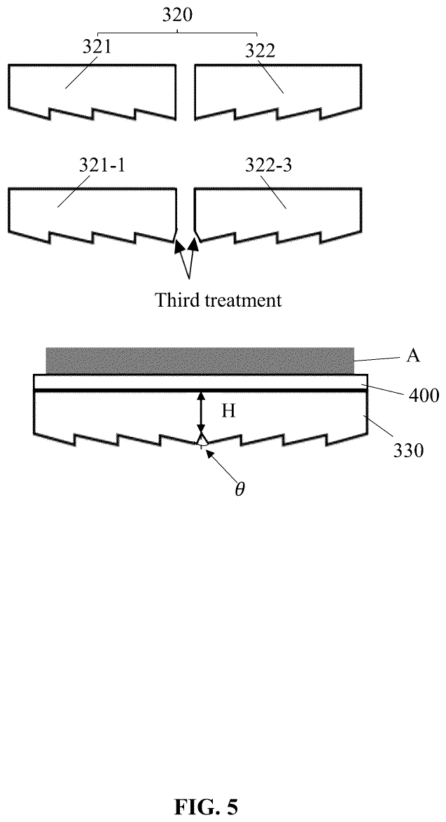

The third treatment may include performing a cutting process on ends of the at least two cut first wafers close to the splicing gap (e.g., a growth end) to form the immersion angle. Merely by way of example, as shown in FIG. 5, the cutting process may be performed on an end of the cut first wafer I 321 and an end of the cut first wafer II 322 close to the splicing gap (e.g., a growth end), respectively, to obtain the cut first wafer I 321-1 after the third treatment and the cut first wafer II 322-3 after the third treatment. Then, splicing the cut first wafer I 321-1 after the third treatment and the cut first wafer II 322-3 after the third treatment is performed to obtain the first seed crystal 330. As shown in FIG. 5, an immersion angle θ may be formed at the splicing gap of the first seed crystal 330.

It should be understood that the immersion angle is provided to allow the solution to better penetrate the splicing gap during crystal growth based on the TSSG method using the first seed crystal, thereby closing the splicing gap by the grown crystal. The immersion angle may have various structures. For example, the immersion angle includes a cylinder, a cone, a polyhedron, etc. Correspondingly, a longitudinal cross-section of the immersion angle may be a polygon, a triangle (as shown in FIG. 5), etc. In some embodiments, the longitudinal cross-section of the immersion angle may also be any other shape capable of increasing the capillary force of the solution at the splicing gap. Merely by way of example, as shown in FIG. 5, the splicing gap may be a cone, and a base circle of the cone is close to an end of the step. A radius of the splicing gap may be understood as a radius of the base circle of the cone, and the immersion angle may be understood as a vertex angle of the cone. The length of the solution penetrating the splicing gap may be calculated by the formula (1) as follows:

$$H = \frac{2 γ cos θ}{ρ gr} , \qquad ( 1 )$$

where H denotes a length of the splicing gap (i.e., a thickness of the first wafer after the first treatment), γ denotes a surface tension of the solution (which may be understood as a raw material melt) in the TSSG method, ρ denotes a density of the solution, g denotes gravitational acceleration, r denotes the radius of the splicing gap, and θ denotes a wetting angle between the solution and the seed crystal (e.g., the first seed crystal).

In some embodiments, an excessively large immersion angle may cause cracks in the grown crystal. Therefore, the immersion angle needs to be less than a preset threshold. In some embodiments, the immersion angle θ may be greater than 0° and less than 20°. In some embodiments, the immersion angle θ may be greater than 2° and less than 18°. In some embodiments, the immersion angle θ may be greater than 4° and less than 16°. In some embodiments, the immersion angle θ may be greater than 6° and less than 14°. In some embodiments, the immersion angle θ may be greater than 8° and less than 12°. In some embodiments, the immersion angle θ may be greater than 9° and less than 10°.

In some embodiments of the present disclosure, by performing the third treatment on the at least two cut first wafers to form the immersion angle at a position of the spliced cut first wafers close to the splicing gap, a capillary force of the solution is enhanced, allowing the solution to better penetrate the splicing gap, and closing the splicing gap by the grown crystal.

In 120, the first wafer after the first treatment is used as a first seed crystal to grow a precursor crystal based on a top-seeded solution growth method.

The top-seeded solution growth (TSSG) method refers to a method for preparing a crystal by dissolving a raw material (e.g., silicon carbide powder) for preparing the crystal in a low-melting-point flux at a high temperature to form a uniform saturated solution, then forming a supersaturated melt by manners such as slow cooling, which causes the crystal to precipitate on a seed crystal.

The precursor crystal refers to an intermediate crystal prepared in the TSSG method.

After bonding one side of the second wafer to the first seed crystal and bonding the other side of the second wafer to the seed crystal holder, the precursor crystal is grown by the TSSG method. Merely by way of example, as shown in FIG. 2, the first wafer 210 after the first treatment is used as the first seed crystal, and the crystal growth layer 220 having a preset thickness is prepared based on the TSSG method. The first wafer 210 after the first treatment and the crystal growth layer 220 may be referred to as the precursor crystal.

It should be understood that when growing the precursor crystal based on the first seed crystal and the TSSG method, due to the limitations of the TSSG method, if the thickness of the prepared crystal growth layer is too large, a large number of macroscopic defects (e.g., solvent inclusions) may occur in the crystal growth layer. Thus, the thickness of the prepared crystal growth layer by the TSSG method needs to satisfy a preset condition. In some embodiments, during the growth of the crystal growth layer of the precursor crystal, the thickness of the crystal growth layer 220 grown based on the TSSG method needs to be controlled within a range of 1 mm to 1.5 mm. In some embodiments, during the growth of the precursor crystal, the thickness of the crystal growth layer 220 grown based on the TSSG method may be controlled within a range of 1.1 mm to 1.4 mm. In some embodiments, during the growth of the precursor crystal, the thickness of the crystal growth layer 220 grown based on the TSSG method may be controlled within a range of 1.2 mm to 1.3 mm.

In some embodiments of the present disclosure, by controlling the thickness of the crystal growth layer prepared by the TSSG method, not only can various defect issues caused by excessive growth thickness of the prepared precursor crystal be reduced, but the preset thickness of the precursor crystal can also ensure that the second treatment can be carried out on the precursor crystal.

In 130, a second treatment is performed on the precursor crystal.

The second treatment may include, but is not limited to, grinding or polishing the precursor crystal or the crystal growth layer of the precursor crystal.

It should be understood that since a surface of the crystal growth layer of the prepared precursor crystal in the TSSG method may be attached with a certain amount of solvent and/or crystalline particles, the second treatment needs to be performed on the precursor crystal or the crystal growth layer thereof. In some embodiments, the second treatment may be performed on the precursor crystal or the crystal growth layer thereof via various means. Merely by way of example, as shown in FIG. 2, the surface of the crystal growth layer 220 may be processed by relative motion between the grinding tool and the crystal growth layer 220 under a preset pressure, so as to improve surface smoothness and flatness of the crystal growth layer 220, reduce surface defects, and obtain the crystal growth layer 230 after the second treatment. In some embodiments, the means of the second treatment may be the same as or different from the means of the first treatment. As shown in FIG. 2, the first wafer 210 after the first treatment and the crystal growth layer 230 after the second treatment may be referred to as the precursor crystal after the second treatment.

In order to prepare a high-quality target crystal, when the precursor crystal after the second treatment is used as a second seed crystal, it is necessary to ensure that the surface of the second seed crystal is sufficiently smooth and flat and has as few defects as possible. In some embodiments, a surface roughness of the second seed crystal may be no greater than 0.2 nm. In some embodiments, the surface roughness of the second seed crystal may be no greater than 0.15 nm. In some embodiments, the surface roughness of the second seed crystal may be no greater than 0.1 nm. In some embodiments, the surface roughness of the second seed crystal may be no greater than 0.05 nm.

In some embodiments of the present disclosure, by performing the second treatment on the precursor crystal to make the surface roughness of the precursor crystal no greater than 0.2 nm when used as the second seed crystal in the PVT method, the surface of the second seed crystal may be smooth and flat, improving the quality of the second seed crystal, and being beneficial for further improving the quality of the target crystal subsequently prepared by the PVT method.

In 140, the precursor crystal after the second treatment is used as a second seed crystal to grow a target crystal based on a physical vapor transport method.

The physical vapor transport (PVT) method refers to a method in which a material decomposes and sublimes into gaseous components under high-temperature conditions, the gaseous components are transported to a seed crystal in a low-temperature zone driven by an axial temperature gradient, and a crystal is deposited and grown on the surface of the seed crystal.

The target crystal may be grown based on the second seed crystal using the PVT method. Merely by way of example, as shown in FIG. 2, the first wafer 210 after the first treatment and the crystal growth layer 230 after the second treatment may serve as a whole as the second seed crystal (which may be referred to as the precursor crystal after the second treatment), and the target crystal growth layer 240 may be obtained based on the second seed crystal using the PVT method. The target crystal may include the first wafer 210 after the first treatment, the crystal growth layer 230 after the second treatment, and the target crystal growth layer 240.

In some embodiments of the present disclosure, a high-quality precursor crystal is prepared based on the TSSG method, and the second treatment is performed thereon to obtain a high-quality second seed crystal. This not only results in a large-sized target crystal, but also ensures the high quality of the target crystal, reducing microscopic defects and macroscopic defects in the target crystal.

It should be noted that the foregoing description of the process 100 is merely for illustration and explanation and does not limit the applicable scope of the present disclosure. Those skilled in the art can make various modifications and changes to the process 100 under the guidance of the present disclosure. However, these modifications and changes still fall within the scope of the present disclosure.

Embodiments of the present disclosure also provide a seed crystal preparation method. The method includes performing a radial cutting on an off-axis seed crystal to obtain at least two seed crystal wafers; and obtaining a target seed crystal by splicing the at least two seed crystal wafers such that the step directions of the spliced seed crystal wafers are opposite. In some embodiments, the method may further include performing at least one of rotation processing or flipping processing on at least one of the at least two seed crystal wafers. In embodiments of the present disclosure, the off-axis seed crystal and the off-axis wafer may be used interchangeably. In some embodiments, the splicing may include splicing the at least two seed crystal wafers by bonding the at least two seed crystal wafers to a wafer. Related descriptions regarding the radial cutting and the splicing may refer to relevant descriptions in other parts of the present disclosure (e.g., FIG. 3A-FIG. 3C), which are not repeated herein.

In some embodiments, a groove may be provided at a preset height on the wafer. Related descriptions regarding the groove may refer to relevant descriptions in other parts of the present disclosure (e.g., FIG. 4A-FIG. 4C), which are not repeated herein.

In some embodiments, the method further includes treating the spliced seed crystal wafers such that the ends of at least two seed crystal wafers close to a splicing gap form an immersion angle. Related descriptions regarding the immersion angle may refer to relevant descriptions in other parts of the present disclosure (e.g., FIG. 5), which are not repeated herein.

In some embodiments of the present disclosure, by performing the radial cutting on the off-axis seed crystal to obtain at least two cut seed crystal wafers, splicing the at least two cut seed crystal wafers, and making the step directions of the spliced cut seed crystal wafers be opposite, the target seed crystal may be obtained. When the target seed crystal is used to grow a crystal based on the TSSG method, since the step directions of the target seed crystal are opposite to the solution flow direction, step bunching behavior can be significantly suppressed, which is beneficial for reducing microscopic defects and macroscopic defects, improving the quality of the prepared crystal, and making an overall morphology of the crystal flatter and smoother.

Basic concepts have been described above. Obviously, to those skilled in the art, the foregoing detailed disclosure is merely an example and does not constitute a limitation to the present disclosure. Although not explicitly stated herein, those skilled in the art may make various modifications, improvements, and amendments to the present disclosure. Such modifications, improvements, and amendments are suggested in the present disclosure. Therefore, such modifications, improvements, and amendments still fall within the spirit and scope of the exemplary embodiments of the present disclosure.

Meanwhile, the present disclosure uses specific words to describe the embodiments of the present disclosure. For example, “one embodiment,” “an embodiment,” and/or “some embodiments” mean that a certain feature, structure, or characteristic is related to at least one embodiment of the present disclosure. Therefore, it should be emphasized and noted that “an embodiment,” “one embodiment,” or “an alternative embodiment” mentioned two or more times in different locations in the present disclosure does not necessarily refer to the same embodiment. Furthermore, certain features, structures, or characteristics in one or more embodiments of the present disclosure may be appropriately combined.

Furthermore, unless explicitly stated in the claims, the order of processing elements and sequences, the use of numbers and letters, or the use of other names in the present disclosure are not used to limit the order of the processes and methods of the present disclosure. Although the foregoing disclosure discusses some inventive embodiments currently considered useful through various examples, it should be understood that such details are for illustrative purposes only. The appended claims are not limited to the disclosed embodiments. Instead, the claims are intended to cover all modifications and equivalent combinations that conform to the substance and scope of the embodiments of the present disclosure. For example, although the implementation of various components described above may be embodied in a hardware device, it may also be implemented as a software-only solution, e.g., an installation on an existing server or mobile device.

Similarly, it should be noted that, in order to simplify the expression disclosed in the present disclosure and thereby aid the understanding of one or more inventive embodiments, various features are sometimes grouped into one embodiment, drawing, or description thereof in the foregoing description of the embodiments of the present disclosure. However, this method does not mean that the object of the present disclosure requires more features than those mentioned in the claims. Rather, claimed subject matter may lie in less than all features of a single foregoing disclosed embodiment.

In some embodiments, numbers describing components and property quantities are used. It should be understood that, for such numbers used in the description of the embodiments, modifiers such as “about,” “approximately,” or “substantially” are used in some examples. Unless otherwise stated, “about,” “approximately,” or “substantially” indicates that the stated number allows a variation of +20%. Accordingly, in some embodiments, the numerical parameters used in the specification and the claims are approximate values, which may vary according to the characteristics required by individual embodiments. In some embodiments, the numerical parameters should consider the specified number of significant digits and adopt the method of general digit retention. Although the numerical ranges and parameters used to confirm the breadth of their scope in some embodiments of the present disclosure are approximate values, in specific embodiments, the setting of such numerical values is as precise as possible within a feasible range.

For each patent, patent application, patent application publication, and other material, such as articles, books, specifications, publications, documents, etc., cited in the present disclosure, the entire contents thereof are hereby incorporated by reference into the present disclosure. Excluded are application history documents that are inconsistent with or conflict with the content of the present disclosure, and documents that limit the broadest scope of the claims of the present disclosure (whether currently or subsequently appended to the present disclosure). It should be noted that if the description, definition, and/or use of terms in the ancillary materials of the present disclosure are inconsistent with or conflict with those in the present disclosure, the description, definition, and/or use of terms in the present disclosure shall prevail.

Finally, it should be understood that the embodiments described in the present disclosure are only used to illustrate the principles of the embodiments of the present disclosure. Other variations may also fall within the scope of the present disclosure. Therefore, by way of example and not limitation, alternative configurations of the embodiments of the present disclosure may be considered consistent with the teachings of the present disclosure. Accordingly, embodiments of the present disclosure are not limited to the embodiments explicitly introduced and described in the present disclosure.

1. A crystal preparation method, comprising:
obtaining a first wafer after a first treatment, wherein the first wafer is an off-axis wafer, and the first treatment comprises:
performing radial cutting on the first wafer to obtain at least two cut first wafers; and
splicing the at least two cut first wafers such that step directions of the spliced cut first wafers are opposite;
using the first wafer after the first treatment as a first seed crystal to grow a precursor crystal based on a top-seeded solution growth method;
performing a second treatment on the precursor crystal; and
using the precursor crystal after the second treatment as a second seed crystal to grow a target crystal based on a physical vapor transport method.

2. The crystal preparation method according to claim 1, wherein a thickness of the first wafer after the first treatment is in a range of 0.35 mm-10 mm.

3. The crystal preparation method according to claim 1, further comprising:
during the growth of the precursor crystal, controlling a thickness of a crystal growth layer grown based on the top-seeded solution growth method to be in a range of 1 mm-1.5 mm.

4. The crystal preparation method according to claim 1, wherein a surface roughness of the second seed crystal is not greater than 0.2 nm.

5. The crystal preparation method according to claim 1, wherein at least one of the first treatment or the second treatment includes at least one of grinding or polishing.

6. (canceled)

7. The crystal preparation method according to claim 1, wherein the first treatment further includes:
performing at least one of rotation processing or flipping processing on at least one of the at least two cut first wafers.

8. The crystal preparation method according to claim 1, wherein the splicing the at least two cut first wafers includes:
splicing the at least two cut first wafers by bonding the at least two cut first wafers to a second wafer.

9. The crystal preparation method according to claim 8, wherein a groove is provided at a preset height on the second wafer.

10. The crystal preparation method according to claim 1, wherein the first treatment further includes:
performing a third treatment on the spliced cut first wafers such that ends of the at least two cut first wafers close to a splicing gap form an immersion angle.

11. A seed crystal preparation method, comprising:
performing radial cutting on an off-axis seed crystal to obtain at least two seed crystal wafers; and
obtaining a target seed crystal by splicing the at least two seed crystal wafers such that step directions of the spliced seed crystal wafers are opposite.

12. The seed crystal preparation method according to claim 11, further comprising:
performing at least one of rotation processing or flipping processing on at least one of the at least two seed crystal wafers.

13. The seed crystal preparation method according to claim 11, wherein the splicing the at least two seed crystal wafers includes:
splicing the at least two seed crystal wafers by bonding the at least two seed crystal wafers to a wafer.

14. The seed crystal preparation method according to claim 13, wherein a groove is provided at a preset height on the wafer.

15. The seed crystal preparation method according to claim 11, further comprising:
performing a treatment on the spliced seed crystal wafers such that ends of the at least two seed crystal wafers close to a splicing gap form an immersion angle.

16. The crystal preparation method according to claim 10, wherein the immersion angle is greater than 0° and less than 20°.

17. The seed crystal preparation method according to claim 15, wherein the immersion angle is greater than 0° and less than 20°.

18. The seed crystal preparation method according to claim 15, further comprising:
growing a precursor crystal based on the target seed crystal and a top-seeded solution growth method;
performing a second treatment on the precursor crystal; and
using the precursor crystal after the second treatment as a final target seed crystal.

19. The crystal preparation method, comprising:
obtaining a target seed crystal based on the seed crystal preparation method according to claim 11; and
growing a target crystal based on the target seed crystal.

20. The crystal preparation method according to claim 19, wherein the growing a target crystal based on the target seed crystal comprises:
growing a precursor crystal based on the target seed crystal and a top-seeded solution growth method; and
growing the target crystal based on the precursor crystal and a physical vapor transport method.

21. The crystal preparation method according to claim 20, wherein the growing the target crystal based on the precursor crystal and a physical vapor transport method comprises:
performing at least one of grinding or polishing on the precursor crystal to obtain a treated precursor crystal; and
growing the target crystal based on the treated precursor crystal and the physical vapor transport method.
